(19) United States
(12) Patent Application Publication
(10) Pub. No.: US 2014/0256143 A1
(43) Pub. Date: Sep. 11, 2014

(54) Method for Hard Mask Loop with Defect Reduction

(71) Applicant: Taiwan Semiconductor Manufacturing Company, Ltd., (US)

(72) Inventor: Zinlar Cheng, Hsin-Chu (TW)

(73) Assignee: Taiwan Semiconductor Manufacturing Company, Ltd., Hsin-Chu (TW)

(21) Appl. No.: 13/792,156

(22) Filed: Mar. 10, 2013

(51) Int. Cl. H01L 21/308; H01L 21/67

(52) U.S. Cl. CPC H01L 21/308; H01L 21/67017
USPC 438/703; 134/157

(57) ABSTRACT

The present disclosure provides one embodiment of a method of fabricating an integrated circuit. The method includes forming a patterned hard mask on a substrate; performing a fabrication process to the substrate through openings of the patterned hard mask; performing a first etch process to remove the patterned hard mask; and applying an NHD solution to the substrate, wherein the NHD solution includes ammonium hydroxide, hydrogen peroxide and deionized water with ratios tuned such that the NHD solution is weak basic.

### BACKGROUND

The integrated circuits scale down along with the advanced technology nodes. The scaling of integrated circuit faces various challenges that include patterning and other fabrication process. For example, field effect transistors (FETs) have been used in conventional integrated circuit (IC) design. Due to shrinking technology nodes, high-k dielectric material and metal are often considered to form a gate stack for a FET. Fin-like active regions are also used to form three dimensional FETs. During the fabrication to pattern various material layers, defects (such as particles) may be present to cause quality and reliability issues. It is more so for advanced technology nodes since a circuit with small feature size is more sensitive to the defects. Especially, when a hard mask is used to pattern various material layers, during its patterning, etching and other processing, the particles introduce concerns in terms of the fabrication integration and device performance. Removing those particles is challenge.

Accordingly, there is a need for a method and a system to address these concerns.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart of a method to make a semiconductor structure constructed according to one embodiment.

FIGS. 2-4 are sectional views of a semiconductor structure made by the method of FIG. 1 at various fabrication stages constructed according to one embodiment.

FIG. 5 is a schematic view of a system used to implement the method of FIG. 1 constructed according to one embodiment.

FIG. 6 is a diagram illustrating characteristics of various particles on the semiconductor structure constructed according to one embodiment.

FIG. 7 is a diagram illustrating characteristics of various cleaning methods constructed according to one embodiment.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

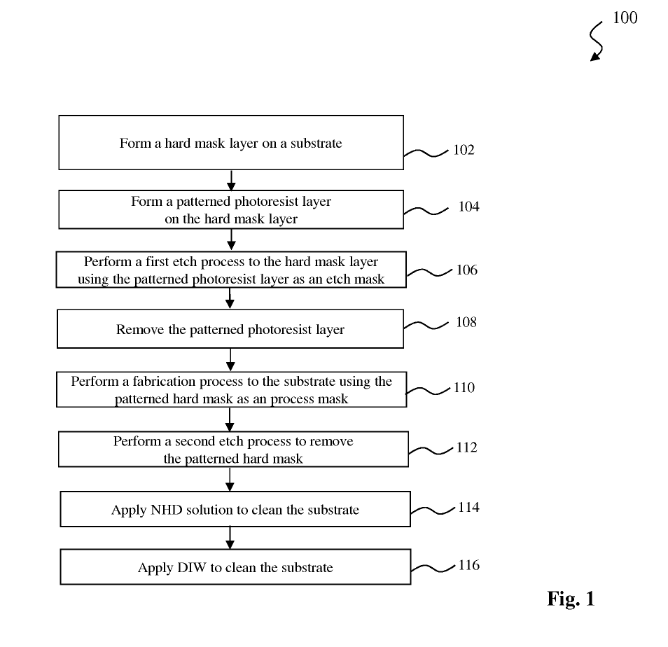

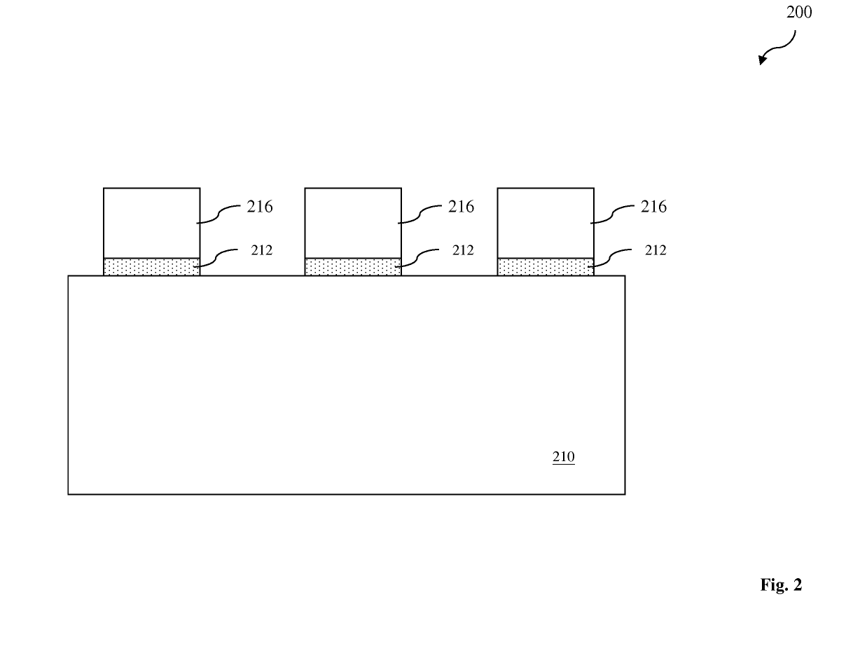

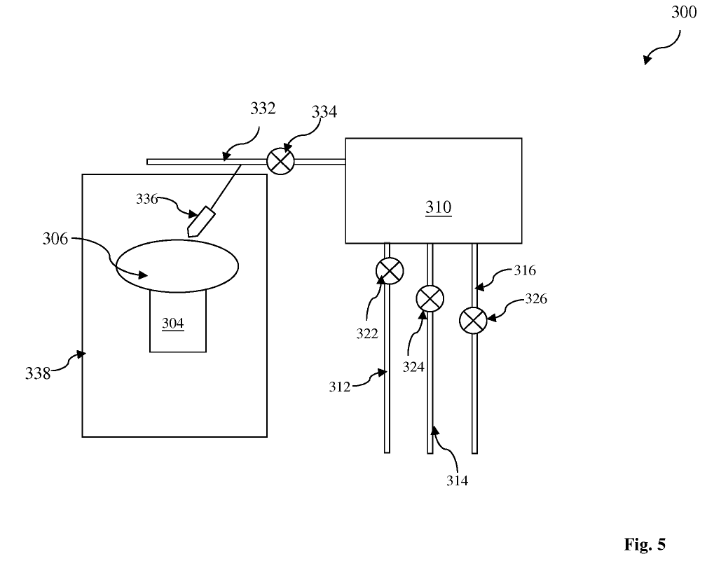

FIG. 1 is a flowchart of a method 100 to make a semiconductor structure constructed according to one embodiment. FIGS. 2-4 are sectional views of a semiconductor structure 200 made by the method 100 at various fabrication stages constructed according to one embodiment. FIG. 5 is a schematic view of a system 300 used in the method 100 constructed according to one embodiment. With reference to FIGS. 1 through 5, the method 100 and the system 200 are collectively described using the semiconductor structure 200 as an example.

Referring to FIG. 2, the semiconductor structure 200 includes a semiconductor substrate 210 of a first semiconductor material. In the present embodiment, the first semiconductor material is silicon. Alternatively, the first semiconductor material may include other proper semiconductor material. In one embodiment, the semiconductor substrate 210 includes a buried dielectric material layer for isolation formed by a proper technology, such as a technology referred to as separation by implanted oxygen (SIMOX). In some embodiments, the substrate 210 may be a semiconductor on insulator, such as silicon on insulator (SOI). The semiconductor substrate 210 may also include various doped features, such as n-type wells and p-type wells disposed in respective active regions.

Referring to FIGS. 1 and 2, the method 200 begins at operation 102 by forming a hard mask layer 212 on the substrate 210. In the present embodiment, the hard mask layer 212 includes titanium nitride (TiN). In other embodiments, the hard mask layer 212 alternatively includes other suitable material, such as silicon carbide, silicon nitride, or silicon oxynitride. The hard mask layer 212 is formed on the substrate 210 by a deposition technique, such as chemical vapor deposition (CVD), Physical vapor deposition (PVD) or other suitable technique.

Still referring to FIGS. 1 and 2, the method 200 proceeds to operation 104 by forming a patterned photoresist layer 216 on the hard mask layer 212 by a lithography process. In one embodiment, the lithography process includes forming a photoresist layer by spin-on coating; exposing the photoresist layer using an exposure energy, such as ultraviolet (UV) light, and developing the exposed photoresist layer to form the patterned photoresist layer using a developing chemical. In another example, the lithography process includes spin-on coating, soft baking, exposing, post-exposure baking, developing and hard baking. In other embodiment, the lithography process to form the patterned photoresist layer 216 may alternatively use other technique, such as e-beam lithography, maskless patterning or molecular print.

Still referring to FIGS. 1 and 2, the method 200 proceeds to operation 106 by performing an etch process to etch the hard mask layer 212 using the patterned photoresist layer 216 as an etch mask. The etch process is designed to selectively remove the hard mask layer 212 through the openings of the patterned photoresist layer 216, resulting in the patterned hard mask, which is also referred by numeral 212. The patterned hard mask 212 has openings such that the substrate 210 is uncovered within the openings. In the present example, the tech process includes a wet etch. Alternatively, the etch process may include any suitable etch technique, such as wet etch, dry etch, a combination thereof, or other suitable etch technique.

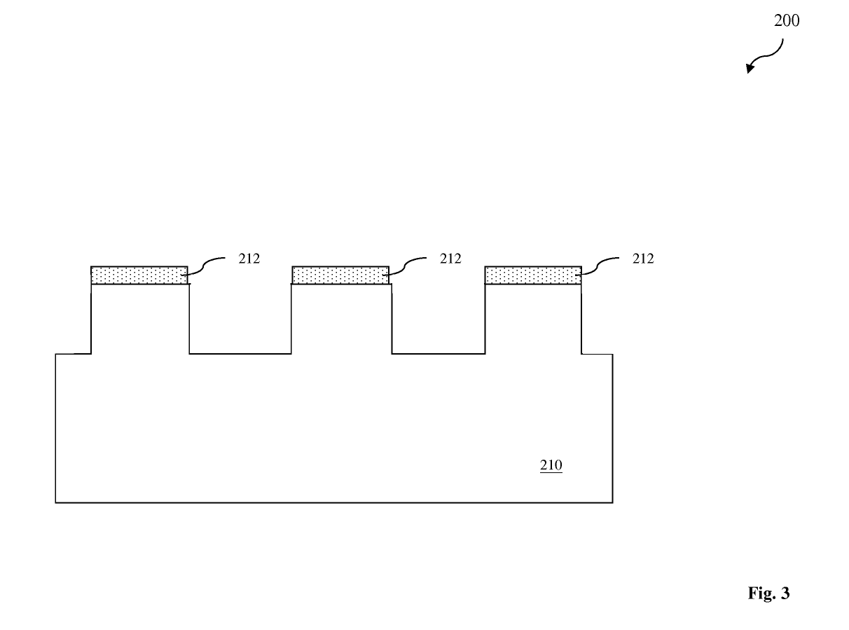

Referring to FIGS. 1 and 3, the method 200 may proceed to operation 108 by removing the patterned photoresist layer 216 using a suitable technique, such as wet stripping or plasma ashing. Alternatively, the removal of the patterned photoresist layer 216 may be executed at a later fabrication stage.

Still referring to FIGS. 1 and 3, the method 200 proceeds to operation 110 by performing a fabrication process to the substrate 210 using the patterned hard mask 212 as a fabrication process hard mask. Particularly, the fabrication process is applied to the substrate 210 through the openings of the patterned hard mask 212. In the present embodiment, the fabrication process is an etch process designed to selectively etch the substrate 210. The patterned hard mask 212 is used as an etch mask. In furtherance of the embodiment, the etch process is designed to etch the semiconductor material (such as silicon) of the substrate 210 to form trenches in the semiconductor substrate 210.

In another embodiment, the fabrication process includes an ion implantation process applied to introduce dopant to the substrate 210. In this case, the patterned hard mask 212 is used as an implantation mask. In furtherance of the embodiment, the ion implantation process is designed to introduce the corresponding dopant to the semiconductor material (such as silicon) of the substrate 210 to form various respective doped features, such as doped wells, in the semiconductor substrate 210.

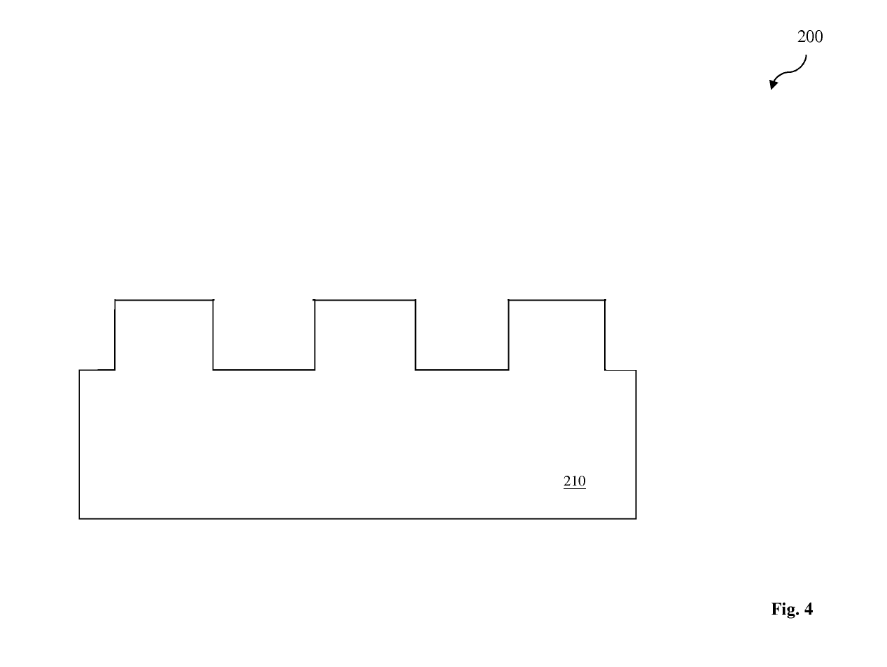

Referring to FIGS. 1 and 4, the method 200 proceeds to operation 112 by performing another etch process to remove the patterned hard mask 212. The etch process is designed to selectively etch the hard mask 212. The etch process in the operation 112 may be similar to the etch process in the operation 106. In various example, the etch process includes dry etch, wet etch, or a combination thereof.

The method 200 proceeds to operation 114 to clean the substrate 210 by applying a chemical solution having ammonium hydroxide (NH₄OH), hydrogen peroxide (H₂O₂) and deionized water (H₂O) with concentration tuned such that the chemical solution is weak basic. The chemical solution is referred to as NHD solution. Particularly, the NHD solution has a pH value tuned in a range between 7 and 12. More particularly, the pH value of the NHD solution is tuned by the content of the deionized water (DIW) in the NHD solution. In the present embodiment, the NHD solution has volume ratios of ammonium hydroxide, hydrogen peroxide and deionized water in a range from about 1:1:100 to about 1:1:1000.

The NHD solution is applied to the substrate 210 by a suitable technique for cleaning effect. For example, the NHD solution is applied to the substrate 210 by spraying for duration of time. In another example, the NHD solution may be heated to a higher temperature before being applied to the substrate 210.

In the present embodiment, the NHD solution is introduced to the substrate 210 by the cleaning system 300 illustrated in FIG. 5. The cleaning system 300 includes substrate stage 304 configured to secure a semiconductor substrate (semiconductor wafer or wafer) 306 and designed with a mechanism operable to spin the wafer secured thereon. The cleaning system 300 also includes a tank 310 as a chemical container to hold the cleaning solution and to provide the cleaning solution for wafer cleaning.

The cleaning system 300 includes various chemical supply components coupled with the tank 310 and designed to provide various chemicals to the tank 310. In the present embodiment, the cleaning system 300 includes a first chemical supply component 312 to provide deionized water to the tank 310, a second chemical supply component 314 to provide hydrogen peroxide to the tank 310, and a third chemical supply component 314 to provide ammonium hydroxide to the tank 310. The chemical supply components are further equipped with control mechanism to control the chemical flow to the tank 310 such that the chemicals are mixed in the tank to form the NHD solution in expected concentration ratios. In the present example, the expected concentration ratios (volume ratios) of the NHD solution range from about 1:1:100 to about 1:1:1000 for ammonium hydroxide, hydrogen peroxide and deionized water. The chemical supply components further include control mechanisms to control the chemical flow, respectively. Particularly, a first control mechanism 322 is integrated with the first chemical supply component 312 to control the corresponding chemical flow. Similarly, a second control mechanism 324 is integrated with the second chemical supply component 314 to control its chemical flow and a third control mechanism 326 is integrated with the third chemical supply component 316 to control its chemical flow. In one embodiment, the chemical control mechanisms include valves to control respective flows. In another embodiment, the control mechanisms further include flow meters coupled with the respective valve for automatic control of the respective chemical flow. The chemical supply components are further connected to respective chemical sources and may be equipped with suitable pump to pump the respective chemical to the tank 310.

The cleaning system 300 also includes another chemical passage component 332 configured between the tank 310 and the wafer stage 304. The chemical passage component 332 is connected to the tank, is further integrated with a controller 334 (such as a valve), and is designed to provide a chemical solution (such as NHD) to the wafer 306 on the wafer stage 304 through a cleaning mechanism, such as a nozzle 336 for spraying.

In one embodiment, the wafer stage 304 is configured in a cleaning chamber 338. In another embodiment, the cleaning system 300 includes one or more filters integrated respectively with the chemical supply components and configured to filter particle from the respective chemicals. In yet another embodiment, the cleaning system 300 includes a plurality of wafer stages configured in one or more chambers for parallel cleaning to multiple wafers with enhanced efficiency and reduced cycle time.

Back to the operation 114, the substrate 210 is sent to the cleaning system 300 for NHD cleaning. In the cleaning system 300, the substrate 210 is secured on the wafer stage 304 and the NHD solution is introduced to the substrate 210 for spin cleaning.

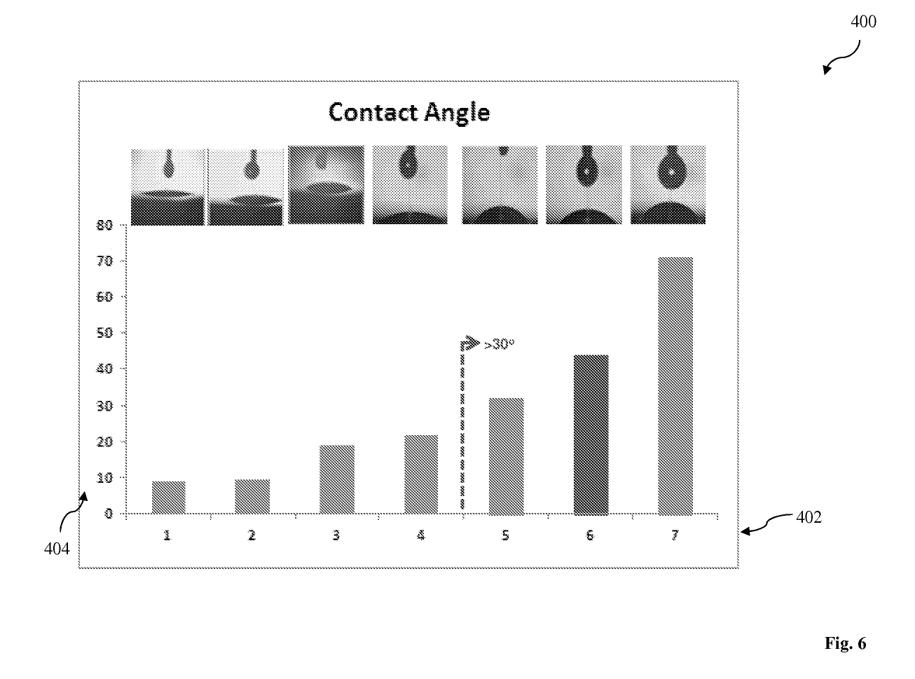

In the existing method to clean the substrate 210 after the removal of the hard mask 212, water is used to clean, which cannot effectively remove the particles that include residues formed the substrate 210 through the reactions among the etchant, the hard mask material and the photoresist material. Various experiments are further illustrated in FIG. 6 according to one embodiment. In a diagram 400 of FIG. 6, the horizontal axis 402 represents 1 to 7 groups of products with different particles. The vertical axis 404 represents the contact angles (water to the particles) from 0 degree to 90°. The experiments show that, for the particles with the contact angle greater than 30°, the particles cannot be effective removed by the existing method using water.

It is identified through experiments that the NHD cleaning is effective due to its chemical characteristic, especially its pH value in the range of 7 to 12. The NHD solution is different from the standard cleaning solution (such as SC-1) since the NHD solution is a weak basic solution with a pH value not greater than 12 while the standard cleaning solution is a strong basic solution with a pH value greater than 12. The tuning the pH value of the cleaning solution to be weak basic is based on the characteristics of the various particles on the substrate 210. Through various experiments, it was found that various particles (such as silicon nitride, aluminum oxide, silicon oxide) present on the substrate 210 have a positive zeta potentials and pH values less than 7 (acid). Those particles are hydrophobic (with high contact angle) and illustrate low removal rate. Furthermore, it was also identified that the particles with a pH value in a range from 7 to 12 and a zeta-potential less than zero have low contact angle and high removal rate. When the NHD solution with a pH value in a range from 7 to 12 is applied to a wafer (substrate), the wafer surface property (Particularly, the particles on the wafer surface) are tuned to be hydrophilic, or having a pH value in a range from 7 to 12 and a zeta-potential less than zero. Accordingly, the corresponding contact angle is reduced and the particles show high removal rate.

Especially, the NHD solution as a weak basic solution, its pH value is not tuned by introducing acid but by tuning the concentration of the deionized water or introducing more deionized water. The reason for this is based on a fact, identified through experiments, that the particles on the substrate 210 are also weak acid and are able to react with the acid in the acid-containing solution to redeposit on the substrate 210, forming new particles or residues on the substrate 210.

Since water has a pH value 7, the diluted solution with the deionized water in the NHD solution has a concentration ratio to ammonium hydroxide from 100 to 2000 and a concentration ratio to hydrogen peroxide from 100 to 2000 such that the pH value of the NHD solution is tuned to a range from 7 to 12.

Back to FIG. 1, the method 100 proceeds to an operation 116 by applying deionized water the substrate 210 for further cleaning, according to the present embodiment. The deionized water may be introduced to the substrate 210 using the cleaning system 300. In this case, the cleaning system 300 is controlled to only provide deionized water to the substrate 210.

Although the method 100 is described according to various embodiments, other operations may present before, during and/or after the operations of the method 100. In one embodiment, after the formation of the trenches in the semiconductor substrate 210, shallow trench isolation (STI) features are formed in the trenches to define various active regions in the semiconductor substrate 210, by a procedure that includes dielectric deposition and chemical mechanical polishing (CMP). In one example, the formation of the STI features includes: filling in the trenches with dielectric material; and performing a chemical mechanical polishing (CMP) process to remove excessive dielectric material above the semiconductor mesa 120. In furtherance of the example, the filling in the trenches with dielectric material includes forming a thermal silicon oxidation layer by oxidation, and thereafter depositing one or more dielectric material (such as silicon oxide) by CVD to fill in the trenches. In another example, the deposition of the dielectric material includes depositing the dielectric material, such as silicon oxide, by high density plasma CVD (HDPCVD).

In another embodiment, fin-like active regions are further formed for fin field effect transistors (FinFETs). In this embodiment, the STI features are formed as described above, then an etch process is applied to the substrate 210 to selectively etch the dielectric material to recess the STI features. In furtherance of the embodiment, the etch process is designed to selectively etch the dielectric material (such as silicon oxide) of the STI features while the semiconductor material (such as silicon) of the substrate 210 remains.

In another embodiment, the operation 112 to remove the patterned hard mask may be implemented at a later fabrication stage, such as after the formation of the STI features.

The method 100 may alternatively be used for other circuit fabrication purposes. In one embodiment, the method 100 is used to form doped wells, such as n-type wells and/or p-type wells. In this case, the operation 110 includes an ion implantation process tuned to form respective doped wells. In another embodiment, the method 100 is used to form various gate stacks for field effect transistors (FETs). For example, various gate materials including gate dielectric material (such as interfacial layer, high dielectric material or combination thereof) and gate electrode (polysilicon, metal, metal alloy, silicide, or combinations thereof) are formed on the substrate 210 before the operation 102 to form the hard mask layer 202. Thereafter, the hard mask layer 202 is formed on the gate materials by the operation 102. Other operations of the method 100 are implemented to form the gate stacks. In this embodiment, the fabrication process of the operation 110 includes an etch procedure to pattern the gate materials using the patterned hard mask 202 as an etch mask. The etch procedure may include one or more etch steps to etch the gate materials. In one example, the etch procedure includes various etch steps tuned to selectively etch various materials of the gate dielectric material and gate electrode, respectively. A high k dielectric material is a dielectric material having a dielectric constant greater than that of thermal silicon oxide. For example, a high k dielectric material includes hafnium oxide (HfO) or other suitable metal oxide. In other examples, the formation of the interfacial layer (silicon oxide in the present example) includes thermal oxidation, atomic layer deposition (ALD), CVD or other suitable technology. The formation of the high k dielectric material layer includes ALD, metalorganic CVD (MOCVD), physical vapor deposition (PVD), or other suitable technology. The formation of the metal layer includes PVD, plating, or other suitable technology. The formation of the polysilicon layer includes CVD or other suitable technology.

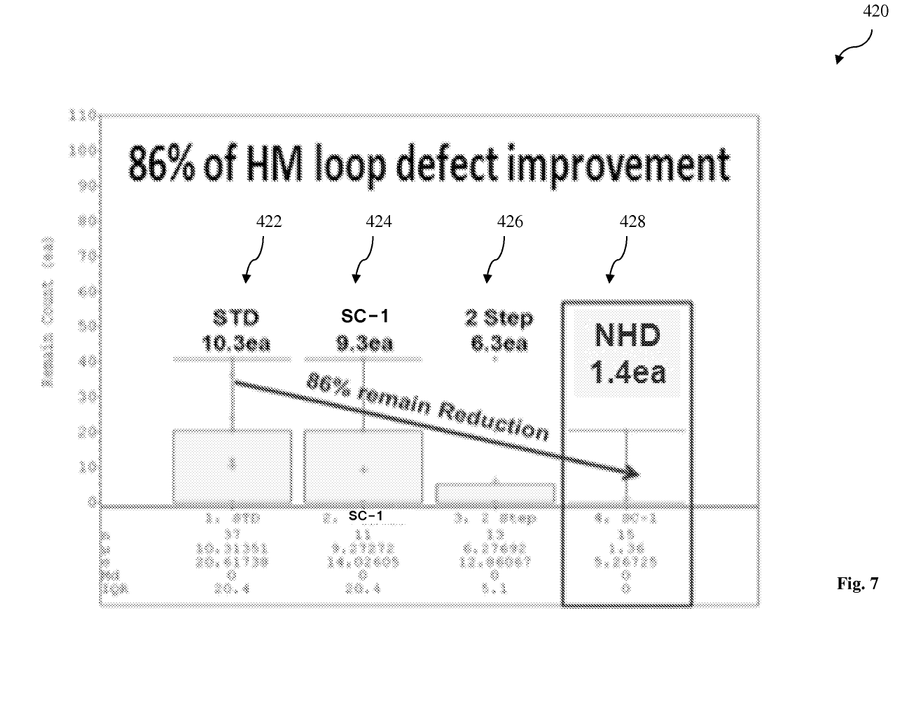

Various advantages are present in different embodiments of the present disclosure. In one embodiment, the disclosed cleaning operation with the NHD solution is more effective than existing methods for the cleaning. Some experimental results are further provided in FIG. 7. The diagram 420 provides comparison among four different cleaning methods. The first cleaning method 422 is standard water cleaning. The second cleaning method 424 is a cleaning procedure including SC-1 and then water. The third cleaning method 426 a cleaning procedure that includes two steps (step 1: SC-1 and water, and step 2: repeat SC-1 and water). The fourth method 428 is the disclosed cleaning method using the NHD solution. In FIG. 7, the vertical axis represents the remaining particle count per wafer after the corresponding cleaning. The horizontal axis lists the four group of cleaning results associated with the four cleaning methods. Various numbers under the horizontal axis includes sample #, remaining particle count, and standard deviation. According to the shown results, the water cleaning method 422 and the SC-1 cleaning method 424 end up with high remaining particle counts (10.3 and 9.3, respectively). The 2-step cleaning method 426 reduces the remaining particle count to 6.3, which is still high. By using the disclosed cleaning method 428 with NHD solution, the remaining particle count is reduced to 1.4. It is 86% reduction of the remaining particle count.

Thus, the present disclosure provides one embodiment of a method for fabricating an integrated circuit. The includes forming a patterned hard mask on a substrate; performing a fabrication process to the substrate through openings of the patterned hard mask; performing a first etch process to remove the patterned hard mask; and applying an NHD solution to the substrate, wherein the NHD solution includes ammonium hydroxide, hydrogen peroxide and deionized water with ratios tuned such that the NHD solution is weak basic.

In one embodiment of the disclosed method, the NHD solution includes ammonium hydroxide, hydrogen peroxide and deionized water with ratios tuned such that a pH value of the NHD solution ranges between about 7 and about 12.

In another embodiment, the method further includes applying deionized water to the substrate after the applying of the NHD solution to the substrate.

In yet another embodiment, the NHD solution includes ammonium hydroxide, hydrogen peroxide and deionized water with volume ratios ranging between 1:1:100 and 1:1:2000.

In yet another embodiment, the patterned hard mask includes titanium nitride. In yet another embodiment, the patterned hard mask includes silicon carbide or silicon nitride.

In yet another embodiment, the forming a patterned hard mask on a semiconductor substrate includes forming a hard mask layer on the substrate; forming a patterned photoresist layer on the hard mask layer; performing a second etch process to remove the patterned hard mask using the patterned photoresist layer as an etch mask; and removing the patterned photoresist layer.

In yet another embodiment, the performing a fabrication process to the substrate through openings of the patterned hard mask includes performing an etch process to the substrate.

In yet another embodiment, the substrate includes silicon; and the etch process is designed to selectively etch silicon.

In yet another embodiment, the performing a fabrication process to the substrate through openings of the patterned hard mask includes performing an ion implantation process to the substrate.

In yet another embodiment, the substrate further includes a material layer; and the performing a fabrication process to the substrate through openings of the patterned hard mask includes performing the fabrication process to the material layer.

The present disclosure also provides another embodiment of a method for fabricating an integrated circuit. The method includes forming a hard mask layer on a semiconductor substrate; forming a patterned photoresist layer on the hard mask layer; performing a first etch process to etch the hard mask layer using the patterned photoresist layer as a first etch mask; removing the patterned photoresist layer; performing a fabrication process to the semiconductor substrate through openings of the patterned hard mask; performing a second etch process to remove the patterned hard mask; thereafter, applying an NHD solution to the substrate, wherein the NHD solution includes ammonium hydroxide, hydrogen peroxide and deionized water with volume ratios tuned such that a pH value of the NHD solution ranges between about 7 and about 12; and thereafter, applying deionized water to the semiconductor substrate.

In one embodiment, the NHD solution includes ammonium hydroxide, hydrogen peroxide and deionized water ammonium hydroxide, peroxide and deionized water with volume ratios ranging between 1:1:100 and 1:1:2000. In another embodiment, the patterned hard mask includes titanium nitride.

In yet another embodiment, the performing a fabrication process to the substrate through openings of the patterned hard mask includes performing an ion implantation process to the semiconductor substrate.

In yet another embodiment, the performing a fabrication process to the semiconductor substrate through openings of the patterned hard mask includes performing an etch process to the semiconductor substrate to form trenches. In yet another embodiment, the method further includes filling the trenches with a dielectric material; performing a chemical mechanical polishing process to the semiconductor substrate, resulting in shallow trench isolation (STI) features; and recessing the STI features to form fin-like semiconductor active regions.

The present disclosure also provides one embodiment of a cleaning system that includes a wafer stage designed to secure a wafer and being operable to spin the wafer; a chemical supply designed to separately provide ammonium hydroxide, hydrogen peroxide and deionized water and being operable to tune volume ratios of the ammonium hydroxide, hydrogen peroxide and deionized water; a tank coupled with the chemical supply and configured to mix the ammonium hydroxide, hydrogen peroxide and deionized water to a NHD solution with a pH value ranging between 7 and 12; and a cleaning mechanism coupled with the tank and designed to introduce the NHD solution to the wafer for cleaning.

In one embodiment of the cleaning system, the chemical supply further includes a control mechanism to independently control flows of the ammonium hydroxide, hydrogen peroxide and deionized water, respectively.

In another embodiment, the chemical supply further includes a monitor mechanism to independently monitor flows of the ammonium hydroxide, hydrogen peroxide and deionized water, respectively, and the monitor mechanism is coupled with the control mechanism.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method of fabricating an integrated circuit, comprising:
forming a patterned hard mask on a substrate;
performing a fabrication process to the substrate through openings of the patterned hard mask;
performing a first etch process to remove the patterned hard mask; and
applying an NHD solution to the substrate, wherein the NHD solution includes ammonium hydroxide, hydrogen peroxide and deionized water with ratios tuned such that the NHD solution is weak basic.

2. The method of claim 1, wherein the NHD solution includes ammonium hydroxide, hydrogen peroxide and deionized water with ratios tuned such that a pH value of the NHD solution ranges between about 7 and about 12.

3. The method of claim 2, further comprising applying deionized water to the substrate after the applying of the NHD solution to the substrate.

4. The method of claim 2, wherein the NHD solution includes ammonium hydroxide, hydrogen peroxide and deionized water with volume ratios ranging between 1:1:100 and 1:1:2000.

5. The method of claim 1, wherein the patterned hard mask includes titanium nitride.

6. The method of claim 1, wherein the patterned hard mask includes silicon carbide.

7. The method of claim 1, wherein the forming a patterned hard mask on a semiconductor substrate includes:
forming a hard mask layer on the substrate;
forming a patterned photoresist layer on the hard mask layer;
performing a second etch process to remove the patterned hard mask using the patterned photoresist layer as an etch mask; and
removing the patterned photoresist layer.

8. The method of claim 1, wherein the performing a fabrication process to the substrate through openings of the patterned hard mask includes performing an etch process to the substrate.

9. The method of claim 8, wherein
the substrate includes silicon; and
the etch process is designed to selectively etch silicon.

10. The method of claim 1, wherein the performing a fabrication process to the substrate through openings of the patterned hard mask includes performing an ion implantation process to the substrate.

11. The method of claim 1, wherein
the substrate further includes a material layer; and
the performing a fabrication process to the substrate through openings of the patterned hard mask includes performing the fabrication process to the material layer.

12. A method of fabricating an integrated circuit, comprising:
forming a hard mask layer on a semiconductor substrate;
forming a patterned photoresist layer on the hard mask layer;
performing a first etch process to etch the hard mask layer using the patterned photoresist layer as a first etch mask;
removing the patterned photoresist layer;
performing a fabrication process to the semiconductor substrate through openings of the patterned hard mask;
performing a second etch process to remove the patterned hard mask;
thereafter, applying an NHD solution to the substrate, wherein the NHD solution includes ammonium hydroxide, hydrogen peroxide and deionized water with volume ratios tuned such that a pH value of the NHD solution ranges between about 7 and about 12; and
thereafter, applying deionized water to the semiconductor substrate.

13. The method of claim 12, wherein the NHD solution includes ammonium hydroxide, hydrogen peroxide and deionized water ammonium hydroxide, peroxide and deionized water with volume ratios ranging between 1:1:100 and 1:1:2000.

14. The method of claim 12, wherein the patterned hard mask includes titanium nitride.

15. The method of claim 12, wherein the performing a fabrication process to the substrate through openings of the patterned hard mask includes performing an ion implantation process to the semiconductor substrate.

16. The method of claim 12, wherein the performing a fabrication process to the semiconductor substrate through openings of the patterned hard mask includes performing an etch process to the semiconductor substrate to form trenches.

17. The method of claim 16, further comprising:
filling the trenches with a dielectric material;
performing a chemical mechanical polishing process to the semiconductor substrate, resulting in shallow trench isolation (STI) features; and
recessing the STI features to form fin-like semiconductor active regions.

18. A cleaning system, comprising:
a wafer stage designed to secure a wafer and being operable to spin the wafer;
a chemical supply designed to separately provide ammonium hydroxide, hydrogen peroxide and deionized water and being operable to tune volume ratios of the ammonium hydroxide, hydrogen peroxide and deionized water;
a tank coupled with the chemical supply and configured to mix the ammonium hydroxide, hydrogen peroxide and deionized water to a NHD solution with a pH value ranging between 7 and 12; and
a cleaning mechanism coupled with the tank and designed to introduce the NHD solution to the wafer for cleaning.

19. The system of claim 18, wherein the chemical supply further includes a control mechanism to independently control flows of the ammonium hydroxide, hydrogen peroxide and deionized water, respectively.

20. The system of claim 18, wherein the chemical supply further includes a monitor mechanism to independently monitor flows of the ammonium hydroxide, hydrogen peroxide and deionized water, respectively, and the monitor mechanism is coupled with the control mechanism.
